(19) United States
(12) Patent Application Publication
(10) Pub. No.: US 2022/0157945 A1
(43) Pub. Date: May 19, 2022

(54) SIC EPITAXIAL WAFER, MANUFACTURING APPARATUS OF A SIC EPITAXIAL WAFER, FABRICATION METHOD OF A SIC EPITAXIAL WAFER, AND SEMICONDUCTOR DEVICE

(71) Applicant: ROHM CO., LTD., Kyoto-shi (JP)

(72) Inventor: Kentaro TAMURA, Kyoto-shi (JP)

(21) Appl. No.: 17/667,201

(22) Filed: Feb. 8, 2022

Related U.S. Application Data
(62) Division of application No. 15/362,378, filed on Nov. 28, 2016.
Application No. 15/362,378 is a continuation of application No. PCT/JP2015/066208, filed on Jun. 4, 2015.

(30) Foreign Application Priority Data
Jun. 6, 2014 (JP) 2014-117310

(51) Int. Cl. H01L 29/16; H01L 29/872; H01L 29/47; H01L 29/417; H01L 29/49; H01L 29/423; H01L 29/04; H01L 29/06; H01L 21/02; C30B 25/20; C23C 16/32; C30B 25/18; C30B 29/36; H01L 29/34; H01L 29/78

(52) U.S. Cl. CPC H01L 29/1608; H01L 29/74; H01L 29/47; H01L 29/417; H01L 29/49; H01L 29/423; H01L 29/045; H01L 29/0615; H01L 21/02433; C30B 25/20; C23C 16/325; C30B 25/186; C30B 29/36; H01L 21/02378; H01L 21/02529; H01L 21/0262; H01L 29/04; H01L 29/34; H01L 29/7802; H01L 29/7813; H01L 29/872

(57) ABSTRACT

The SiC epitaxial wafer includes a substrate, and an SiC epitaxial growth layer disposed on the substrate, wherein an Si compound gas is used for a supply source of Si, and a Carbon (C) compound gas is used as a supply source of C, for the SiC epitaxial growth layer, wherein any one or both of the Si compound gas and the C compound gas is provided with a compound gas containing Fluorine (F), as the supply source. The Si compound is generally expressed with SiₙHₓCl_{y}F_{z} (n>=1, x>=0, y>=0, z>=1, x+y+z=2n+2), and the C compound is generally expressed with CₘH_{q}ClᵣFₛ (m>=1, q>=0, r>=0, s>=1, q+r+s=2m+2) . There are provided a high quality SiC epitaxial wafer having few surface defects and having excellent film thickness uniformity and carrier density uniformity, a manufacturing apparatus of such an SiC epitaxial wafer, a fabrication method of such an SiC epitaxial wafer, and a semiconductor device.

### CROSS REFERENCE TO RELATED APPLICATIONS

This is a continuation application (CA) of PCT Application No. PCT/JP2015/066208, filed on Jun. 4, 2015, which claims priority to Japan Patent Application No. P2014-117310 filed on Jun. 6, 2014 and is based upon and claims the benefit of priority from prior Japanese Patent Application No. P2014-117310 filed on Jun. 6, 2014 and PCT Application No. PCT/JP2015/066208, filed on Jun. 4, 2015, the entire contents of each of which are incorporated herein by reference.

### FIELD

The embodiment described herein relates an SiC epitaxial wafer, a manufacturing apparatus of the SiC epitaxial wafer, a fabrication method of the SiC epitaxial wafer, and a semiconductor device.

### BACKGROUND

In recent years, much attention has been given to Silicon Carbide (SiC) semiconductors capable of realizing high breakdown voltage, high current use, low on resistance, high degree of efficiency, power consumption reduction, high speed switching, etc., compared with silicon semiconductors.

In conventional SiC epitaxial growths, monosilane (SiH₄), trichlorosilane (SiHCl₃), dichlorosilane (SiH₂Cl₂), tetrachlorosilicane (SiCl₄), etc. have been applied as supply sources of Si. Bonding of these materials is expressed by Si—H bond or Si—Cl bond.

On the other hand, there have been also known SiC epitaxial wafers capable of fabricating high quality and high reliability elements, using SiC epitaxial growth layers in which step bunching being equal to or less than predetermined linear density is formed.

### SUMMARY

Since Si—H bonding energy is lower than Si—Cl bonding energy, the Si—H bond dissociates more excessively than the Si—Cl bond at an SiC epitaxial growth temperature. As a result of the Si—H bond excessively dissociates, it reacts in a vapor phase before materials are reached to a substrate for epitaxial growth, thereby generating particles. Consequently, the generated particles will generate defects on the epitaxial wafer surface, and thereby reducing a yield rate, and reducing the quality of the epitaxial wafers.

In such an excessive vapor phase reaction, it is difficult to supply wafers excellent in uniformity, since a rate of the dissociated materials and unreacted materials is changed during the materials flow, thereby effecting a thickness distribution and a density distribution.

The embodiment provides a high quality SiC epitaxial wafer having few surface defects and having excellent film thickness uniformity and carrier density uniformity, a manufacturing apparatus of such an SiC epitaxial wafer, a fabrication method of such an SiC epitaxial wafer, and a semiconductor device.

According to one aspect of the embodiments, there is provided a silicon carbide epitaxial wafer comprising: a substrate; and an SiC epitaxial growth layer disposed on the substrate, wherein a surface-roughness defect density including particles on a surface of the SiC epitaxial growth layer is less than 1.0 cm⁻².

According to another aspect of the embodiments, there is provided a fabrication method of a silicon carbide epitaxial wafer comprising: preparing an SiC ingot, cutting the prepared SiC ingot with an off angle, and polishing the cut SiC ingot to form an SiC bare wafer; removing a cut surface of the SiC bare wafer to form an SiC substrate; and

crystal-growing an SiC epitaxial growth layer on the SiC substrate, wherein a material gas to be supplied at the time of the epitaxial growth comprises an Si compound gas used as a supply source of Si, and Carbon (C) compound gas used as a supply source of C, wherein any one or both of the Si compound gas and the C compound gas comprises a compound gas containing Fluorine (F), wherein a surface-roughness defect density including particles on a surface of the SiC epitaxial growth layer is controlled to be less than 1.0 cm⁻².

According to still another aspect of the embodiments, there is provided a manufacturing apparatus of a silicon carbide epitaxial wafer, the manufacturing apparatus comprising: a gas injection port; a gas exhaust port; a heating unit; and a reactor, wherein a material gas to be supplied at the time of the epitaxial growth comprises an Si compound gas used as a supply source of Si, and Carbon (C) compound gas used as a supply source of C, wherein any one or both of the Si compound gas and the C compound gas comprises a compound gas containing Fluorine (F), wherein the silicon carbide epitaxial wafer is formed so that a surface-roughness defect density including particles on a surface of the SiC epitaxial growth layer is less than 1.0 cm⁻².

According to yet another aspect of the embodiments, there is provided a semiconductor device to which the above-mentioned silicon carbide epitaxial wafer is applied.

According to the embodiment, there can be provided the high quality SiC epitaxial wafer having few surface defects and having excellent film thickness uniformity and carrier density uniformity, the manufacturing apparatus of the SiC epitaxial wafer, the fabrication method of the SiC epitaxial wafer, and the semiconductor device.

### BRIEF DESCRIPTION OF DRAWINGS

FIG. 1 is a diagram for summarizing Si, C, N, and F bonding energies.

FIG. 2 is a diagram showing temperature dependencies of growth rates, in an Si epitaxial growth according to a comparative example.

FIG. 3 is a diagram for summarizing growth conditions, i.e., materials, growth rates, temperature ranges, and allowed oxidizers, in the Si epitaxial growth according to the comparative example.

FIG. 4 is a diagram showing temperature dependency of growth rates, in an SiC epitaxial growth of an SiC epitaxial wafer according to an embodiment.

FIG. 5 is a schematic bird's-eye view configuration diagram showing the SiC epitaxial wafer according to the embodiment.

FIG. 6A is a schematic bird's-eye view configuration diagram showing a unit cell of a 4H—SiC crystal applicable to the SiC epitaxial wafer according to the embodiment.

FIG. 6B is a schematic configuration diagram showing a two layer portion of the 4H—SiC crystal applicable to the SiC epitaxial wafer according to the embodiment.

FIG. 6C is a schematic configuration diagram showing the unit cell of the 4H—SiC crystal applicable to an SiC epitaxial wafer according to the embodiment.

FIG. 7 is a schematic configuration diagram showing the unit cell of the 4H—SiC crystal shown in FIG. 6A observed from directly above a (0001) surface.

FIG. 8A is a process chart of: preparing a hexagonal-crystal SiC ingot; cutting the SiC ingot with an off angle θ with respect to the (0001) surface; and then polishing the cut SiC ingot to form a plurality pieces of SiC bare wafers, in a schematic bird's-eye view structure diagram showing a fabrication method of the SiC epitaxial wafer according to the embodiment.

FIG. 8B is a process chart of removing the cut surfaces ((0001) surface) of the SiC bare wafer by equal to or greater than 500 nm, after a machining process, in the schematic bird's-eye view structure diagram showing the fabrication method of the SiC epitaxial wafer according to the embodiment.

FIG. 8C is a process chart of forming an oxide film on a principal surface of the SiC substrate by applying an oxidation treatment to the principal surface (0001) surface of the SiC substrate, in the schematic bird's-eye view structure diagram showing the fabrication method of the SiC epitaxial wafer according to the embodiment.

FIG. 8D is a process chart of forming an SiC epitaxial growth layer on the SiC substrate, in the schematic bird's-eye view structure diagram showing the fabrication method of the SiC epitaxial wafer according to the embodiment.

FIG. 9 shows an example of an epitaxial quality image of the SiC epitaxial wafer according to the embodiment, in a case where a surface-roughness defect density including particles on the wafer is approximately 0.07 cm⁻² (the number of defects is 12 (in a case of a wafer having a diameter of 150 mmΦ)).

FIG. 10 shows an example of an epitaxial quality image of the SiC epitaxial wafer according to the comparative example in a case where a surface-roughness defect density including particles on the wafer is approximately 1 cm⁻² (the number of defects is 173 (in a case of a wafer having a diameter of 150 mmΦ)).

FIG. 11 is a diagram showing a relationship between growth temperature and time (example 1 of chemical-vapor deposition (CVD) temperature profile), in the SiC epitaxial growth according to the embodiment.

FIG. 12 is a diagram showing a relationship between growth temperature and time (example 2 of CVD temperature profile), in the SiC epitaxial growth according to the embodiment.

FIG. 13 is a diagram showing a relationship between growth temperature and time (example 3 of CVD temperature profile), in the SiC epitaxial growth according to the embodiment.

FIG. 14 is a schematic configuration diagram showing a first manufacturing apparatus applicable to the SiC epitaxial growth according to the embodiment.

FIG. 15 is a schematic configuration diagram showing a second manufacturing apparatus applicable to the SiC epitaxial growth according to the embodiment.

FIG. 16 is a schematic configuration diagram showing a third manufacturing apparatus applicable to the SiC epitaxial growth according to the embodiment.

FIG. 17 is a schematic configuration diagram showing a fourth manufacturing apparatus applicable to the SiC epitaxial growth according to the embodiment.

FIG. 18 is a schematic cross-sectional structure diagram showing a Schottky barrier diode fabricated with the SiC epitaxial wafer according to the embodiment.

FIG. 19 is a schematic cross-sectional structure diagram showing a trench-gate type MOSFET fabricated with the SiC epitaxial wafer according to the embodiment.

FIG. 20 is a schematic cross-sectional structure diagram showing a planar-gate type MOSFET fabricated with the SiC epitaxial wafer according to the embodiment.

### DESCRIPTION OF EMBODIMENTS

Next, the embodiment will be described with reference to drawings. In the description of the following drawings, the identical or similar reference numeral is attached to the identical or similar part. However, it should be noted that the drawings are schematic and therefore the relation between thickness and the plane size and the ratio of the thickness differs from an actual thing. Therefore, detailed thickness and size should be determined in consideration of the following explanation.

Of course, the part from which the relation and ratio of a mutual size differ also in mutually drawings is included.

Moreover, the embodiment shown hereinafter exemplifies the apparatus and method for materializing the technical idea; and the embodiment does not specify the material, shape, structure, placement, etc. of each component part as the following. The embodiment may be changed without departing from the spirit or scope of claims.

### COMPARATIVE EXAMPLE

FIG. 2 shows temperature dependencies of growth rates, in an Si epitaxial growth according to a comparative example. In FIG. 2, the dashed line SL indicates a boundary between a Diffusion Control region DC and a Kinetic Control region KC in the Si epitaxial growth.

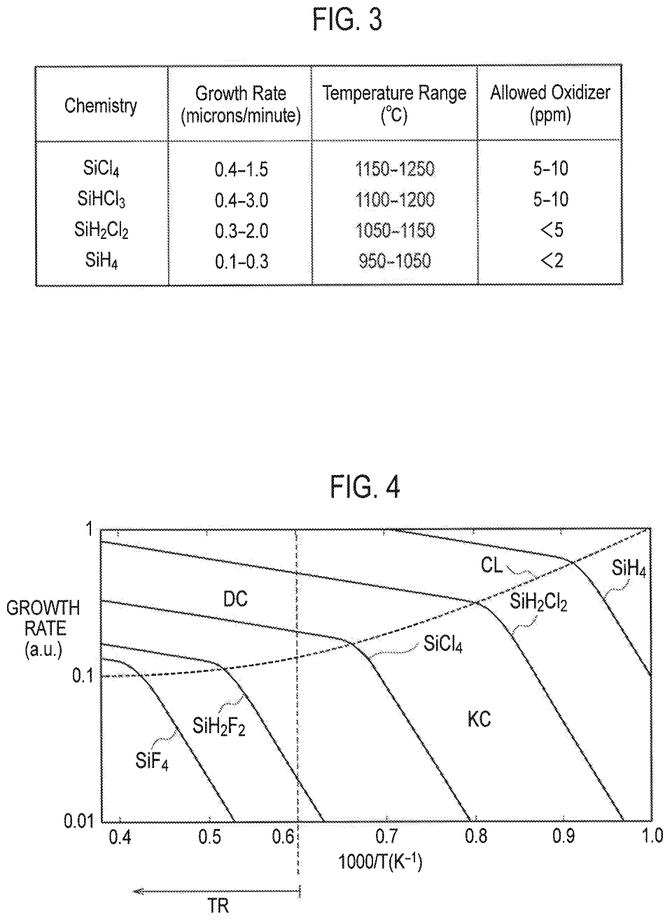

FIG. 3 shows growth conditions, i.e., materials, growth rates, temperature ranges, and allowed oxidizers, in the Si epitaxial growth according to the comparative example. In this case, the oxidizer is vapor etc. which is supplied from a reactor or a susceptor, and is necessary to be reduced to equal to or less than an allowed amount.

In the Si epitaxial growth according to the comparative example, SiN₄, SiHCl₃, SiH₂Cl₂, SiCl₄, etc. are applied as supply sources of Si used as materials.

In the Si epitaxial growth according to the comparative example: the growth rate is 0.4 to 1.5 (μm/min) and the growth temperature is 1150 degrees C (Celsius) to 1250 degrees C. when using SiCl₄; the growth rate is 0.4 to 3.0 (μm/min) and the growth temperature is 1100 degrees C. to 1200 degrees C. when using SiHCl₃; the growth rate is 0.3 to 2.0 (μm/min) and the growth temperature is 1050 degrees C. to 1150 degrees C. when using SiH₂Cl₂; and the growth rate is 0.1 to 0.3 (μm/min) and the growth temperature is 950 degrees C. to 1050 degrees C. when using SiN₄.

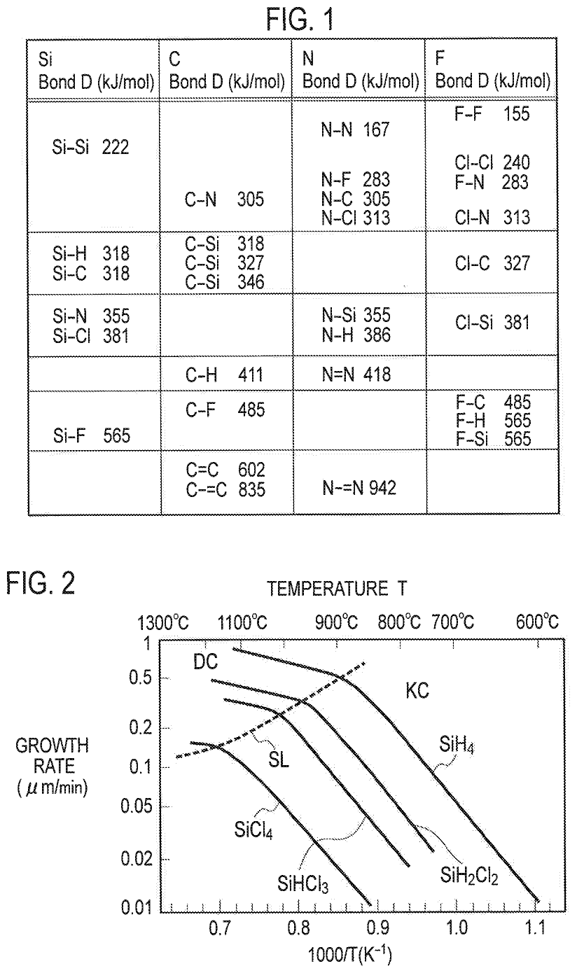

Si, C, N, F, and Cl bonding energies D (kJ/mol) are respectively and generally expressed, as shown in FIG. 1. For example, Si—Si bonding energy is 222 (kJ/mol). On the other hand, Si—C bonding energy is 318 (kJ/mol), Si—N bonding energy is 355 (kJ/mol), Si—Cl bond energy is 381 (kJ/mol), and Si—F bonding energy is 565 (kJ/mol).

Moreover, C—N bonding energy is 305 (kJ/mol), C—Si bonding energy is 318 (kJ/mol), C—C bonding energy is 346 (kJ/mol), C—H bonding energy is 411 (kJ/mol), C—F bonding energy is 485 (kJ/mol), C═C bonding energy is 602 (kJ/mol), and C—═=C bond energy is 835 (kJ/mol).

Moreover, N—N bonding energy is 167 (kJ/mol), N—F bonding energy is 283 (kJ/mol), N—C bonding energy is 305 (kJ/mol), N—Cl bonding energy is 313 (kJ/mol), N—Si bonding energy is 355 (kJ/mol) , N—H bonding energy is 386 (kJ/mol), N═N bonding energy is 418 (kJ/mol), and N—═N bonding energy is 942 (kJ/mol).

On the other hand, F—F bonding energy is 155 (kJ/mol), Cl—Cl bonding energy is 240 (kJ/mol), F—N bonding energy is 283 (kJ/mol), Cl—N bonding energy is 305 (kJ/mol), Cl—N bonding energy is 313 (kJ/mol), Cl—C bonding energy is 327 (kJ/mol), Cl—Si bonding energy is 381 (kJ/mol), F—C bonding energy is 485 (kJ/mol), F—C bonding energy is 485 (kJ/mol), F—H bonding energy is 565 (kJ/mol), and F—Si bonding energy is 565 (kJ/mol).

In this case, if it is assumed that the SiC epitaxial growth temperature is approximately 1600 degrees C., for example, the Si—H bond dissociates more excessively than the Si—Cl bond at the SiC epitaxial growth temperature since the Si—H bonding energy is lower than the Si—Cl bonding energy. As a result of the Si—H bond excessively dissociates, it reacts in a vapor phase before materials are reached to a substrate for epitaxial growth, thereby generating particles. Consequently, since the generated particles generate defects, e.g. particles, downfall, and triangular defects, on the epitaxial wafer surface, a region which can be used as a device is limited as a result, thereby reducing the quality of the epitaxial wafers.

Although dissociation temperature using the Si—Cl bond becomes higher than that of the Si—H bond, the Si—Cl bond will also excessively dissociate at the SiC epitaxial growth temperature equal to or greater than 1600 degrees C.

Similarly, also in a case where all bonds contained in compounds bonds using materials of C expressed with C—H bond, C—C bond, and C—Cl bond, it is not enough to reduce the vapor phase reaction, at the SiC epitaxial growth temperature. It is also similar also when applying compound materials simultaneously containing Si and C.

In addition, there is a further problem in such an excessive vapor phase reaction. A rate of the dissociated materials and unreacted materials is always changed, during the materials flow. Thereby effecting a thickness distribution and a density distribution, it becomes difficult to supply wafers excellent in uniformity.

### Embodiment

FIG. 4 shows temperature dependency of growth rates, in an SiC epitaxial growth of an SiC epitaxial wafer according to an embodiment. In FIG. 4, the dashed line CL indicates a boundary between a mass transport rate-controlled (Diffusion Control) region DC and a surface kinetic rate-controlled (Kinetic Control) region KC in the SiC epitaxial growth. In FIG. 4, a region indicated with the arrow TR is a temperature range applicable to the SiC epitaxial growth, and the temperature range is equal to or greater than approximately 1600 degrees C., for example. An upper limit to the temperature range is approximately 2700 degrees C. near a melting point, for example. The temperature range applicable to the SiC epitaxial growth is preferable within a range from approximately 1600 degrees C. to approximately 2200 degrees C.

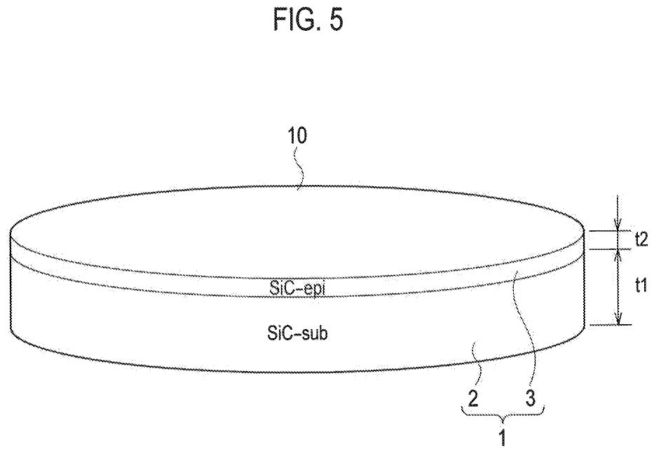

As shown in FIG. 5, the SiC epitaxial wafer 1 according to the embodiment includes a substrate 2, and an SiC epitaxial growth layer 3 disposed on the substrate 2. In the embodiment, an Si compound is used for a supply source of Si, and a Carbon (C) compound is used as a supply source of C, for the SiC epitaxial growth layer. Moreover, any one or both of the Si compound and the C compound is provided with a compound containing Fluoride (F), as the supply source.

The Si compound may contain any one material of SiF₄, SiH₃F, SiH₂F₂, or SiHF₃, for example. Si—F bond exists in the materials, e.g. SiF₄, SiH₃F, SiH₂F, and SiHF₃. Other compounds containing chlorine (Cl) may be used as the Si compound.

Moreover, the Si compound generally can be expressed with the following equation: namely, the Si compound may contain materials expressed with SiₙHₓCl_{y}F_{z} (where n>=1, x>=0, y>=0, z>=1, x+y+z=2n+2).

Moreover, the C compound may contain any one material of CF₄, C₂F₆, C₃F₈, C₄F₆, C₄F₈, C₅F₈, CHF₃, CH₂F₂, CH₃F, or C₂HF₅. C—F bond exists in the materials, e.g. CF₄, C₂F₆, C₃F₈, C₄F₆, C₄F₈, C₅F₈, CH₃F, CH₂F₂, CHF₃, and C₂HF₅. Other compounds containing chlorine (Cl) may be used as the C compound.

Moreover, the C compound generally can be expressed with the following equation: namely, the C compound may contain materials expressed with CₘH_{q}ClᵣFₛ (m>=1, q>=0, r>=0, s>=1, g+r+s=2m+2).

Moreover, the SiC epitaxial growth layer 3 may contain any one material of 4H—SiC, 6H—SiC, 2H—SiC, or 3C—SiC.

The substrate may contain material expressed with any one of 4H—SiC, 6H—SiC, BN, AlN, Al₂O₃, Ga₂O₃, diamond, carbon, or graphite.

In the SiC epitaxial growth for the SiC epitaxial wafer according to the embodiment, at least one of H₂, Ar, HCl, and the F₂ is applicable as carrier gas.

Since the Si—F bonding energy is higher than the Si—H bonding energy or Si—Cl bonding energy, the Si—F bond is suitable for the SiC epitaxial growth. There is a feature that the vapor phase reaction can be reduced since the Si—F bond is not easily dissociated even at a high temperature equal to or greater than 1600 degrees C. As a result of the vapor phase reaction being reduced, generation of defects, e.g. particles, downfall, and triangular defects, is suppressed. Accordingly, a manufacturing yield can be improved, a region which cannot be utilized for a device formation due to defects can be reduced, and thereby a wafer having improved quality can be provided.

Since the reaction rate is limited in a temperature on the substrate surface, it is not affected by distribution of the supply concentration, and therefore temperature uniformity affects film thickness uniformity and carrier density uniformity. Thereby, the SiC epitaxial growth excellent in controllability can be realized.

In the state where the reaction rate is limited in the temperature, many pieces (e.g., several tens or more pieces) of the SiC epitaxial wafers can easily be grown, and thereby the productivity enhancement of the epitaxial wafers can be improved.

In the SiC epitaxial growth, it is a surface kinetic rate-controlled region KC at a relatively low temperature side (right-hand side of the border line CL in FIG. 4), and it is set a mass transport rate-controlled (diffusion control) region DC at a relatively high temperature side (left-hand side of the border line CL in FIG. 4). A temperature for switching from the surface kinetic rate-control to the mass transport rate-control becomes higher, as the bonding energy of materials becomes higher. For example, SiH₄ is composed of only Si—H bond having a relatively low bonding energy.

SiH₄ is in a relatively low temperature side, and SiH₂Cl₂ and SiCl₄ containing Si—Cl bond (Si—Cl bonding energy is higher than Si—H bonding energy) is contained are in a temperature side relatively higher than SiH₄.

Moreover, SiH₂F₇ and SiF₄ containing Si—F bond (Si—F bonding energy is higher than Si—Cl bonding energy) are in a relatively high temperature side. A temperature region required for the SiC epitaxial growth corresponds to a region indicated by the arrow TR on the left-hand side apart from 0.6 in the horizontal axis shown in FIG. 4. Accordingly, as the materials for the surface kinetic rate-controlled, materials containing the Si—F bond are preferable in this temperature region.

### SiC Epitaxial Wafer

FIG. 5 shows a schematic bird's-eye view configuration of the SiC epitaxial wafer according to the embodiment.

The SiC epitaxial wafer 1 contains 4H—SiC, for example, and includes an SiC substrate 2, and an SiC epitaxial growth layer 3 stacked on the SiC substrate 2. A thickness t1 of the SiC substrate 2 is approximately 200 μm to approximately 500 μm, for example, and a thickness t2 of the SiC epitaxial growth layer 3 is approximately 4 μm to approximately 100 μm, for example.

### Crystal Structure

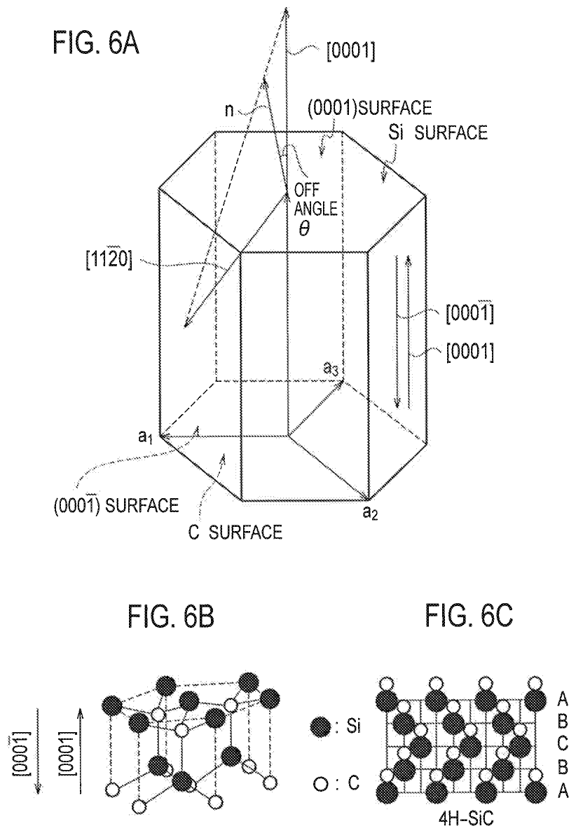

FIG. 6A shows a schematic bird's-eye view configuration of a unit cell in a 4H—SiC crystal applicable to the SiC epitaxial wafer 1 according to the embodiment, FIG. 6B shows a schematic configuration of a two layer portion of the 4H—SiC crystal, and FIG. 6C shows a schematic configuration of four layer portion of the 4H—SiC crystal.

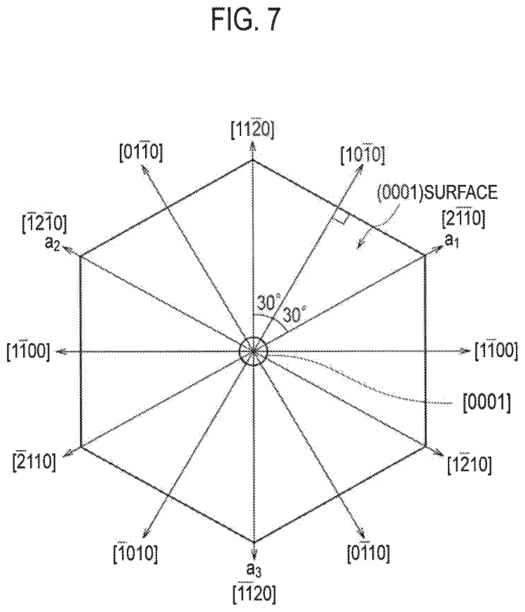

Moreover, FIG. 7 shows a schematic configuration of the unit cell of the 4H—SiC crystal structure of shown in FIG. 6A observed from directly above a (0001) surface.

As shown in FIGS. 6A to 6C, the crystal structure of the 4H—SiC can be approximated with a hexagonal system, and four C atoms are bound with respect to one Si atom. Four C atoms are positioned at four vertexes of a regular tetrahedron in which the Si atom is disposed at a center thereof. In the four C atoms, one Si atom is positioned in [0001] axis direction with respect to the C atom, and other three C atoms are positioned at a [000-1] axis side with respect to the Si atom.

The [0001] axis and [000-1] axis are along the axial direction of the hexagonal prism, and a surface (top surface of the hexagonal prism) using the [0001] axis as a normal line is (0001) surface (Si surface). On the other hand, a surface (bottom surface of the hexagonal prism) using the [000-1] axis as a normal line is (000-1) surface (C surface).

Moreover, directions vertical to the [0001] axis, and passing along the vertexes not adjacent with one another in the hexagonal prism observed from directly above the (0001) surface are respectively a1 axis [2-1-10], a2 axis [−12-10], and a3 axis [−1-120].

As shown in FIG. 7, a direction passing through the vertex between the al axis and the a2 axis is [11-20] axis, a direction passing through the vertex between the a2 axis and the a3 axis is [−2110] axis, and a direction passing through the vertex between the a3 axis and the a1 axis is [1-210] axis.

The axes which are incline at an angle of 30 degrees with respect to each axis of the both sides, and used as the normal line of each side surface of the hexagonal prism, between each of the axes of the above-mentioned six axes passing through the respective vertexes of the hexagonal prism, are respectively [10-10] axis, [1-100] axis, [0-110] axis, [−1010] axis, [−1100] axis, and [01-10] axis, in the clockwise direction sequentially from between the al axis and the [11-20] axes. Each surface (side surface of the hexagonal prism) using these axes as the normal line is a crystal surface right-angled to the (0001) surface and the (000-1) surface.

### Fabrication Method of SiC Epitaxial Wafer

A fabrication method of the SiC epitaxial wafer according to the embodiment includes: preparing an SiC ingot, cutting the prepared SiC ingot with an off angle, and polishing the cut SiC ingot to form an SiC bare wafer; removing a cut surface of the SiC bare wafer to form an SiC substrate; forming an oxide film on a principal surface of the SiC substrate; removing the oxide film; and crystal-growing an SiC epitaxial growth layer on the SiC substrate. In the embodiment, a material gas to be supplied contains an Si compound gas used as a supply source of Si, and C compound gas used as a supply source of C. Moreover, any one or both of the Si compound gas and the C compound gas is provided with a compound gas containing F.

The SiC bare wafer was obtained by cutting the 4H—SiC ingot with an off angle of 4 degrees in the [11-20] axis direction with respect to the (0001) surface. A diameter of the wafer is approximately 150 mm.

Subsequently, the surface where the SiC bare wafer is cut out is subjected to the polishing process, and then a suitable surface for the epitaxial wafer was obtained. In the polishing process, including a bevel process of the wafer edge, etc., the polished surface was finished by utilizing a chemical effect since it is not sufficiently able to remove processing damage merely by mechanical processes.

Before the epitaxial growth, the polished surface is sufficiently washed in order to clean the surface. In the embodiment, RCA washing, brush washing, functional-water washing, megasonic washing, etc. can be used, as a washing method.

A pressure in a reactor after disposing the wafer is kept at approximately 1 kPa to approximately 100 kPa, for example. H₂ used as a carrier gas of the materials is supplied into the reactor. An Ar gas may be supplied thereinto instead of H₂.

By mixing HCl or HF to the carrier gas, a vapor phase reaction can be reduced, generation of particles on the epitaxial wafer can be suppressed, and thereby a high quality wafer can be supplied.

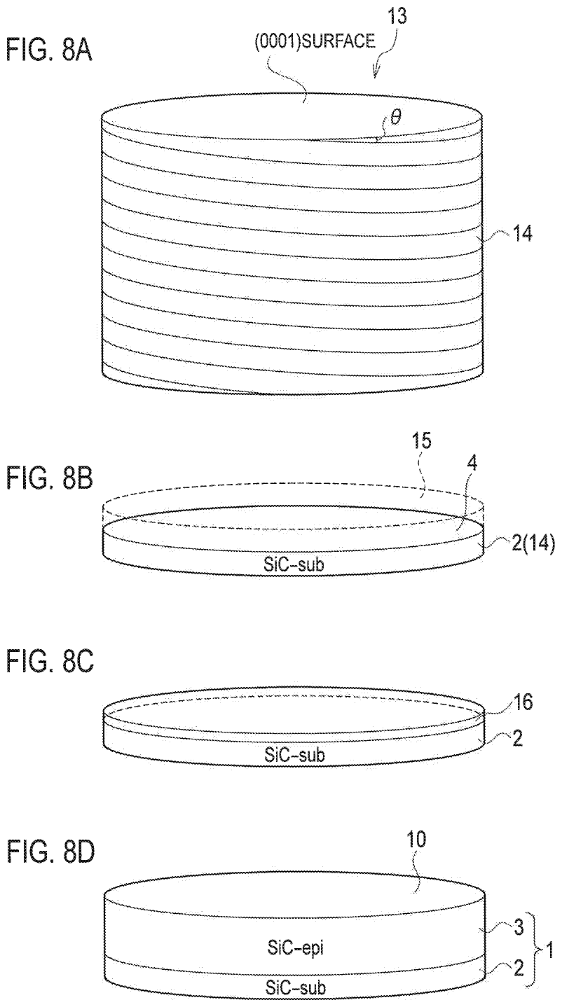

FIG. 8A shows the processing step of preparing a hexagonal-crystal SiC ingot 13, and cutting the SiC ingot 13 with an off angle θ with respect to the (0001) surface, and polishing the cut SiC ingot 13 to form a plurality pieces of SiC bare wafers 14, in a schematic bird's-eye view configuration showing the fabrication method of the SiC epitaxial wafer according to the embodiment. Moreover, FIG. 8B shows the processing step of removing the cut surface 15 of the SiC bare wafer 14 after the machining process. Furthermore, FIG. 8C shows the processing step of forming an oxide film on the principal surface 4 of the SiC substrate 2 by applying an oxidation treatment to the principal surface 4 of the SiC substrate 2. Still further, FIG. 8D shows the processing step of forming an SiC epitaxial growth layer 3 on the SiC substrate 2.

(a) Firstly, as shown in FIG. 8A, the hexagonal-crystal SiC ingot 13 is prepared. Subsequently, a plurality pieces of the SiC bare wafers 14 are obtained by cutting the SiC ingot 13 with the off angle θ of equal to or less than 4 degrees in the [11-20] axis direction with respect to the (0001) surface. Next, the cut surface 15 ((0001) surface) of the SiC bare wafer 14 is polished by a machining process, such as lap processing etc.
(b) Subsequently, as shown in FIG. 8B, the cut surface 15 ((0001) surface) is removed by equal to or greater than approximately 500 nm, for example. As a removing method, Chemical Mechanical Polishing (CMP) technology, plasma etching technology, etc. are applicable, for example. Preferably, plasma etching may be applied. Although it is required for several hours for CMP with less damage to remove the surface by equal to or greater than 500 nm since the SiC is an extremely hard material, the removing process will be completed in a short time, e.g., approximately 20 minutes, if the plasma etching is used. On the other hand, with regard to the cut surface 15 of the SiC bare wafer 14, the damage received by the plasma etching is small since the SiC is extremely hard. The damaged layer on the cut surface 15 of the SiC bare wafer 14 generated by the machining process after the cutting process is sufficiently removed by the above-mentioned removing process, and thereby the SiC substrate 2 having a thickness t1 of approximately 200 μm to approximately 500 μm is obtained.
(c) Subsequently, as shown in FIG. 10C, an oxidation treatment is applied on the principal surface 4 ((0001) surface) of the SiC substrate 2, and thereby the oxide film 16 is formed on the principal surface 4 of the SiC substrate 2. The oxidation treatment may be performed with a dry oxidation method or a wet oxidation method. Although illustration is omitted, the aforementioned oxide film 16 is formed also in a back side surface and a peripheral surface of the SiC substrate 2. Then, the oxide film 16 is removed using a fluoric acid (HF). By applying the formation process and the removing process of the oxide film 16, the damaged layer which cannot be removed by neither the CMP nor the plasma etching, and an altered layer (damaged layer) generated at the time of applying the CMP or plasma etching can be certainly removed from the cut surface 15 of the SiC bare wafer 14. The formation process and the removing process for the oxide film 16 may be performed only after the removing treatment of the cut surface 15 by equal to or greater than 500-nm thickness, but also only before the removing treatment or also before and after the removing treatment.
(d) Subsequently, as shown in FIG. 10D, the SiC epitaxial growth layer 3 is crystal-grown on the SiC substrate 2.

As the materials, SiF₄ and C₃F₈ are supplied thereinto, for example. SiF₄ and C₃F₈ are respectively diluted with H₂ gas, and then are supplied into the reactor. A dilution concentration is 10%, but it is not limited to such a concentration value.

The epitaxial growth temperature may be approximately 1600 degrees C., for example, and may properly be approximately 1750 degrees C.

As a result of inspecting the epitaxially-grown wafer surface, a surface-roughness defect density containing particles on the wafer was equal to or less than 0.07 cm⁻². Namely, only approximately ten defects are generated on a 150 mm wafer (wafer having a diameter of 150 mmΦ), and thereby a high quality wafer with few surface unevenness defects can be obtained.

The off angle of the wafer may be smaller than 4 degrees. Moreover, the growth surfaces may be the C surface, the (11-20) surface, or the (10-10) surface.

6H—SiC can also be used therefor instead of 4H—SiC. The wafer is heated at a temperature equal to or greater than 1600 degrees C., and the C₃H₈ diluted with hydrogen is supplied into the reactor, in order to perform the SiC homoepitaxial growth. SiHF₃ can also be used for the materials instead of SiF₄.

CHF₃ is used therefor instead of C₃H₈, in order to perform the epitaxial growth at a high temperature equal to or greater than 1800 degrees C.

Si—F bonding energy is higher than Si—H bonding energy or Si—Cl bonding energy. The bond having such a high bonding energy is not easily dissociated even at the high temperature, thereby reducing the excessive reaction.

In the SiC epitaxial wafer according to the embodiment and the manufacturing apparatus, the dissociation of bonding for the materials containing the Si—F bond begins at a temperature suitable for the SiC epitaxial growth. As a result, the vapor phase reaction is reduced, and thereby generation of defects, e.g. particles, downfall, and triangular defects, is suppressed. Accordingly, a manufacturing yield can be improved, a region which cannot be utilized for a device formation due to defects can be reduced, and thereby a wafer having improved quality can be provided.

Furthermore, since the reaction rate is limited to the substrate concentration rather than the supply concentration, temperature uniformity is directly led to film thickness uniformity and carrier density uniformity. Accordingly, the high quality SiC epitaxial wafer excellent in the uniformities can be obtained.

Similarly, C—F bonding energy is higher than C—H bonding energy, C—Cl bonding energy, and C—C bonding energy. Accordingly, a still higher effect is produced by using in combination with compounds containing the Si—F bond.

### Growth Temperature Range

A lower limit of the growth temperature range is approximately 1400 degrees C. The lower limit of the temperature of the apparatus is strictly dependent on a flow rate and a flow velocity of hydrogen in the reactor. The lower limit is increased, since hydrogen takes heat from the SiC epitaxial wafer, as the flow rate and the flow velocity of hydrogen become larger. Conversely, the heat taken by hydrogen from the SiC epitaxial wafer becomes smaller, as the flow rate and the flow velocity of hydrogen become smaller. Accordingly, the lower limit is decreased since the surface temperature of the SiC epitaxial wafer is increased compared with the case where the flow rate and the flow velocity of hydrogen relatively large. Since stacking faults will be easily generated during the SiC epitaxial growth if the growth temperature is relatively low, a stacking fault density of the SiC epitaxial wafer surface will also be increased. The stacking fault density can be estimated by photoluminescence (PL) imaging, for example.

The upper limit of the growth temperature range can be allowed up to near the melting point, in physical properties. As a problem at the apparatus side, if the upper limit of the temperature is increased, a cost and structure of the apparatus will be varied. Moreover, since time required for increasing the temperature is also increased, it is not preferable that the temperature is too high also in terms of cost. Accordingly, it is preferable to grow up at a relatively low temperature in the light of a balance of a fabricating cost. However, there is a problem peculiar to SiC that the stacking fault density becomes higher at a relatively low temperature, and the temperature during the epitaxial growth is increased in order to reduce the stacking fault density. Accordingly, the optimal temperature range may be approximately 1600 degrees C. to approximately 1750 degrees C.

More preferably, the optimal temperature is approximately 1750 degrees C. which is a temperature where the stacking fault density can be sufficiently reduced. However, such an optimal temperature also depends on the flow rate and the flow velocity of hydrogen in the reactor, for the above-mentioned reason.

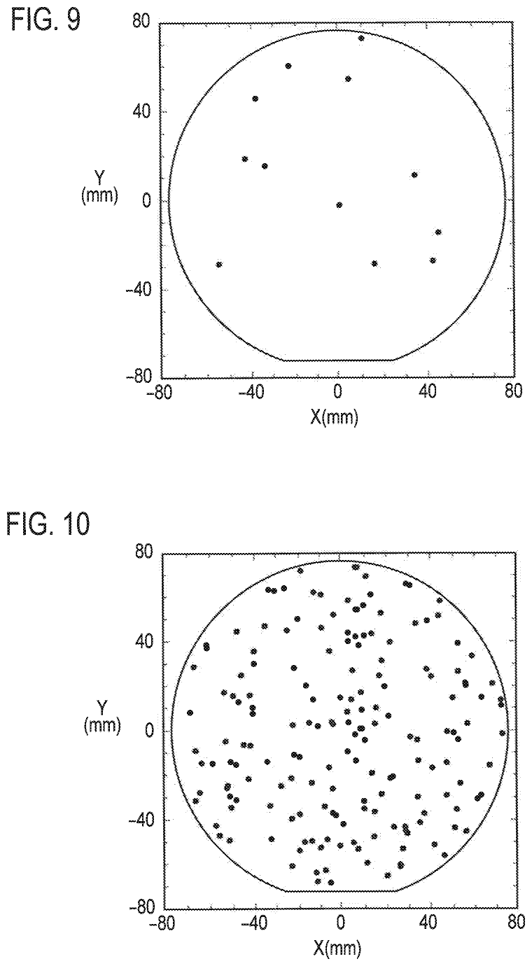

FIG. 9 shows an example of an epitaxial quality image of the SiC epitaxial wafer according to the embodiment. In the SiC epitaxial wafer according to the embodiment, a surface-roughness defect density (approximately 0.07 cm⁻²) containing particles on the wafer is obtained. This value is equivalent to an example where the number of defects is 12 in a wafer having a diameter of 150 mmΦ.

FIG. 10 shows an example of an epitaxial quality image of the SiC epitaxial wafer according to the comparative example. In the SiC epitaxial wafer according to the comparative example, a surface-roughness defect density containing particles on the wafer is approximately 1.00 cm⁻². This value is equivalent to an example where the number of defects is 173 in a wafer having a diameter of 150 mmΦ.

### CVD Temperature Profile

### Profile Example 1

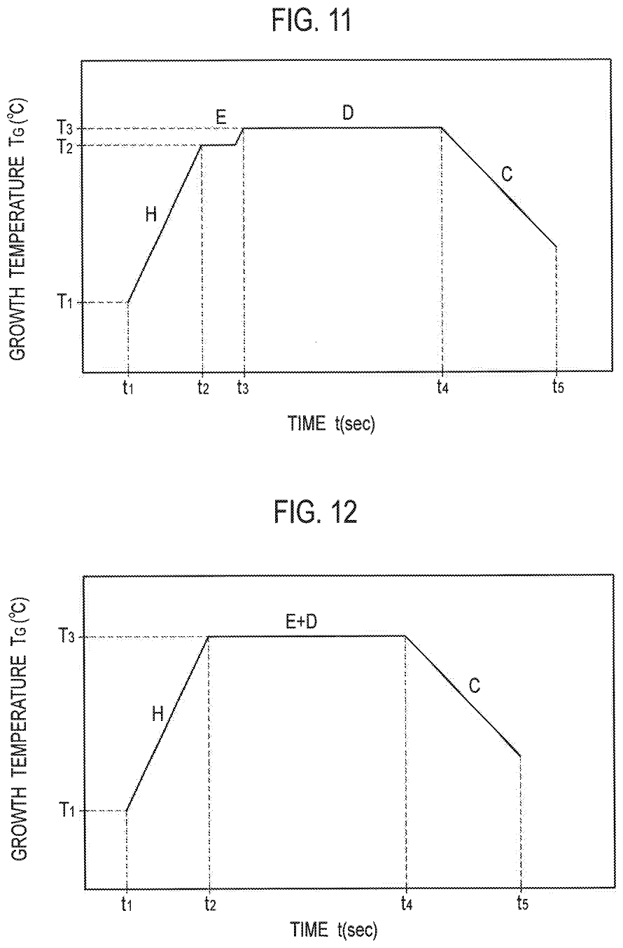

FIG. 11 shows an example 1 of a CVD temperature profile showing a relationship between growth temperature T_{G} (degrees C.) and time t, in the SiC epitaxial growth according to the embodiment.

The example 1 of the CVD temperature profile corresponds to a case where a predetermined temperature of the hydrogen etching (in-situ Etching) immediately before depositing the SiC epitaxial growth layer is lower than a predetermined temperature of depositing the SiC epitaxial growth layer. In FIG. 11, the straight line H expresses a period of temperature rise, the straight line E expresses a period of hydrogen etching, the straight line D expresses a period of SiC epitaxial growth, and the straight line C expresses a period of temperature fall.

When the hydrogen gas is used as the carrier gas, a value of specific heat and a coefficient of thermal conductivity of the hydrogen gas are larger than those of other gases. Therefore, the hydrogen gas has properties, i.e., a capacitance of heat is larger and the heat is easily conducted. When the flow rate of hydrogen is varied, the temperature of the wafer surface is also varied even if a predetermined temperature of a susceptor is the same as each other. Since the hydrogen flow rate and the temperature of the wafer surface are correlated with each other, the optimal hydrogen etching temperature varies in accordance with the hydrogen flow rate.

The example 1 of the CVD temperature profile shows an example where the predetermined temperature T₂ of the hydrogen etching immediately before the deposition of SiC epitaxial growth layer is set so as to be lower than the predetermined temperature T₃ of the deposition of SiC epitaxial growth layer, as shown in FIG. 11.

### Profile Example 2

FIG. 12 shows an example 2 of the CVD temperature profile showing the relationship between growth temperature T_{G} (degrees C.) and time t, in the SiC epitaxial growth according to the embodiment.

The example 2 of the CVD temperature profile corresponds to a case where the predetermined temperature of the hydrogen etching immediately before depositing the SiC epitaxial growth layer is equal to the predetermined temperature of depositing the SiC epitaxial growth layer. In FIG. 12, the straight line H expresses a period of temperature rise, the straight lines E+D express a period of hydrogen etching and a period of SiC epitaxial growth, and the straight line C expresses a period of temperature fall.

As mentioned above, when the flow rate of hydrogen is varied, the temperature of the wafer surface is also varied even if a predetermined temperature of a susceptor is the same as each other. Since the hydrogen flow rate and the temperature of the wafer surface are correlated with each other, the optimal hydrogen etching temperature varies in accordance with the hydrogen flow rate.

The example 2 of the CVD temperature profile shows an example where the predetermined temperature of the hydrogen etching immediately before the deposition of SiC epitaxial growth layer is set so as to be equal to the predetermined temperature T₃ of the deposition of SiC epitaxial growth layer, as shown in FIG. 12.

### Profile Example 3

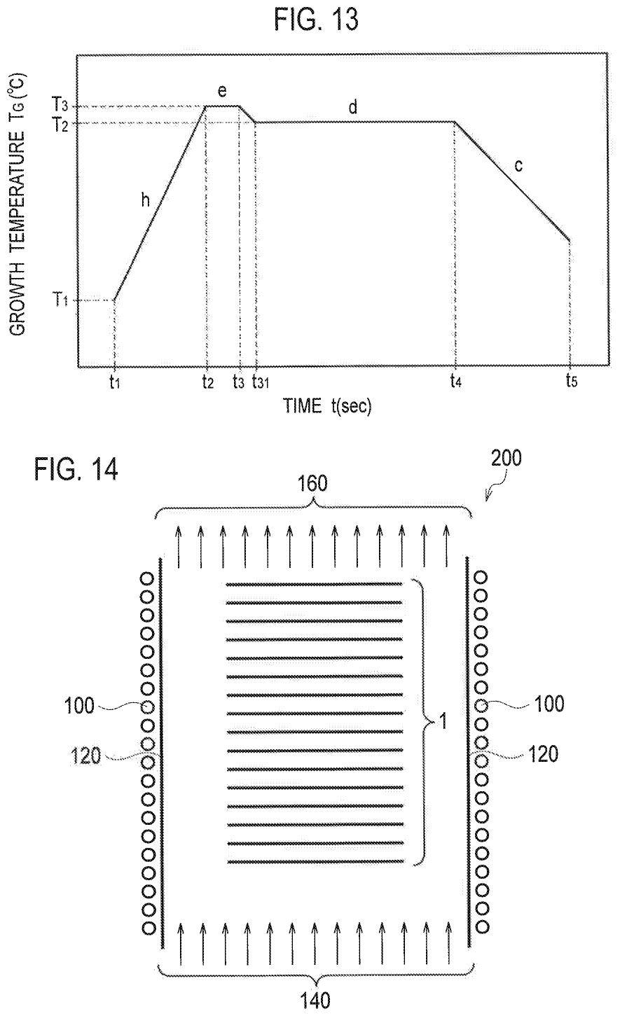

FIG. 13 shows an example 3 of the CVD temperature profile showing the relationship between growth temperature T_{G} (degrees C.) and time t, in the SiC epitaxial growth according to the embodiment.

The example 3 of the CVD temperature profile corresponds to a case where the predetermined temperature of the hydrogen etching immediately before depositing the SiC epitaxial growth layer is higher than the predetermined temperature of depositing the SiC epitaxial growth layer. In FIG. 13, the straight line H expresses a period of temperature rise, the straight line E expresses a period of hydrogen etching, the straight line D expresses a period of SiC epitaxial growth, and the straight line C expresses a period of temperature fall.

As mentioned above, when the flow rate of hydrogen is varied, the temperature of the wafer surface is also varied even if a predetermined temperature of a susceptor is the same as each other. Since the hydrogen flow rate and the temperature of the wafer surface are correlated with each other, the optimal hydrogen etching temperature varies in accordance with the hydrogen flow rate.

The example 3 of the CVD temperature profile shows an example where the predetermined temperature T₂ of the hydrogen etching immediately before the deposition of SiC epitaxial growth layer is set so as to be higher than the predetermined temperature T₃ of the deposition of SiC epitaxial growth layer, as shown in FIG. 13.

### Manufacturing Apparatus

A manufacturing apparatus of the SiC epitaxial wafer according to the embodiment includes a gas injection port, a gas exhaust port, a heating unit, and a reactor. In the embodiment, a material gas to be supplied contains an Si compound gas used as a supply source of Si, and C compound gas used as a supply source of C. Moreover, any one or both of the Si compound gas and the C compound gas is provided with a compound gas containing F.

### First CVD Apparatus

As shown in FIG. 14, in the manufacturing apparatus of the SiC epitaxial wafer according to the embodiment, a schematic configuration example of a first CVD apparatus applicable to the SiC epitaxial growth includes a gas injection port 140, a gas exhaust port 160, a heating unit 100, and a vertical-type reactor 120.

As a heating method of the heating unit 100, resistance heating, induction heating using a coil, lamp heating, etc. are adoptable. In the case of the induction heating method, a structural member made from carbon (not shown in FIG. 14) disposed near the wafer, the structural member made from carbon produces heat, and then the wafer in contact with the structural member is heated or the wafer is heated with radiation from the structural member made from carbon.

In the vertical-type reactor 120, a plurality pieces of the SiC epitaxial wafers 1 can be disposed in a face up manner or face down manner.

While the material gas is supplied from the gas injection port 140 at a lower portion of the vertical-type reactor 120 and then is exhausted from the gas exhaust port 160 at an upper portion of the vertical-type reactor 120, the materials which flows on the surface of the plurality pieces of the SiC epitaxial wafers 1 react, thereby forming the SiC epitaxial growth layer.

The material gas to be supplied generally can be expressed with the following equation: namely, SiₙHₓCl_{y}F_{z} (n>=1, x>=0, y>=0, z>=1, x+y+z=2n+2) and/or CₘH_{q}ClᵣFₛ, (m>=1, q>=0, r>=0, s>=1, q+r+s=2m+2) .

As the carrier gas, at least one of H₂ Ar, HCl, and F₂ is applicable.

As materials for dopant, N₂ or Trimethylaluminium (TMA: (CH₃)₃Al) is applicable.

### Second CVD Apparatus

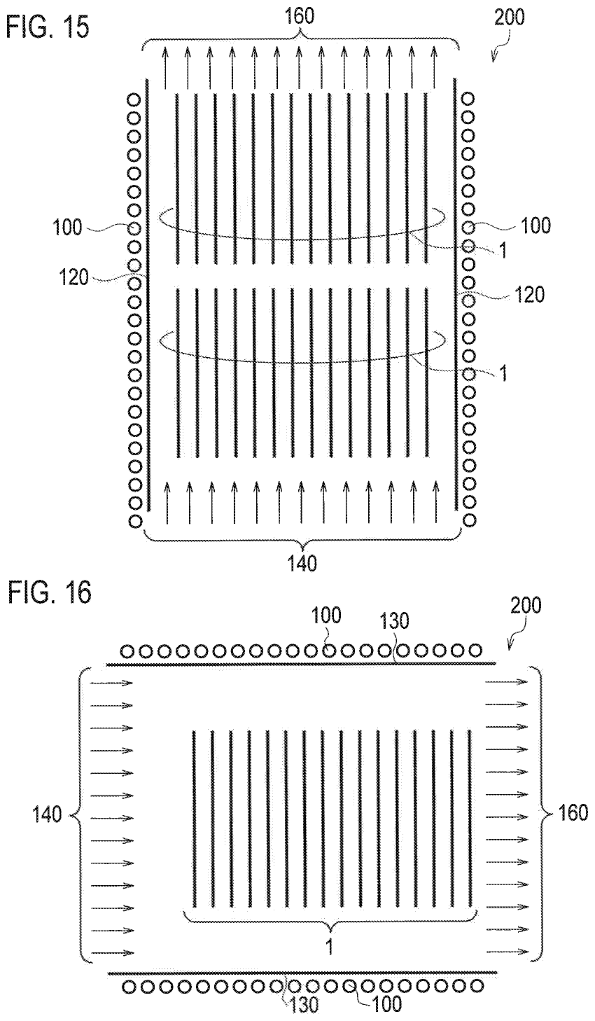

As shown in FIG. 15, in the manufacturing apparatus of the SiC epitaxial wafer according to the embodiment, a schematic configuration example of a second CVD apparatus applicable to the SiC epitaxial growth includes a gas injection port 140, a gas exhaust port 160, a heating unit 100, and a vertical-type reactor 120.

As a heating method of the heating unit 100, resistance heating, induction heating using a coil, lamp heating, etc. are adoptable. In the case of the induction heating method, a structural member made from carbon (not shown in FIG. 14) disposed near the wafer, the structural member made from carbon produces heat, and then the wafer in contact with the structural member is heated or the wafer is heated with radiation from the structural member made from carbon.

In the vertical-type reactor 120, the plurality pieces of the SiC epitaxial wafers 1 are disposed so as to be parallel to the flow of the gas.

While the material gas is supplied from the gas injection port 140 at a lower portion of the vertical-type reactor 120 and then is exhausted from the gas exhaust port 160 at an upper portion of the vertical-type reactor 120, the materials which flows on the surface of the plurality pieces of the SiC epitaxial wafers 1 react, thereby forming the SiC epitaxial growth layer.

The material gas to be supplied generally can be expressed with the following equation: namely, SiₙHₓCl_{y}F_{z} (n>=1, x>=0, y>=0, z>=1, x+y+z=2n+2) and/or CₘH_{q}ClᵣFₛ (m>=1, q>=0, r>=0, s>=1, q+r+s=2m+2).

As the carrier gas, at least one of H₂, Ar, HCl, and F₂ is applicable.

As the materials for dopant, N₂ or TMA is applicable.

### Third CVD Apparatus

As shown in FIG. 16, in the manufacturing apparatus 200 of the SiC epitaxial wafer according to the embodiment, a schematic configuration example of a third CVD apparatus applicable to the SiC epitaxial growth includes a gas injection port 140, a gas exhaust port 160, a heating unit 100, and a horizontal-type reactor 130.

As a heating method of the heating unit 100, resistance heating, induction heating using a coil, lamp heating, etc. are adoptable. In the case of the induction heating method, a structural member made from carbon (not shown in FIG. 14) disposed near the wafer, the structural member made from carbon produces heat, and then the wafer in contact with the structural member is heated or the wafer is heated with radiation from the structural member made from carbon.

In the horizontal-type reactor 130, the plurality pieces of the SiC epitaxial wafers 1 can be vertically arranged in the upward direction stand so as to be opposite to the flow of gas.

While the material gas is supplied from the gas injection port 140 of the horizontal-type reactor 130, passes through the plurality pieces of the SiC epitaxial wafers 1, and then is exhausted from the gas exhaust port 160, the materials which flows on the surface of the plurality pieces of the SiC epitaxial wafers 1 react, thereby forming the SiC epitaxial growth layer.

The material gas to be supplied generally can be expressed with the following equation: namely, SiₙHₓCl_{y}F_{z} (n>=1, x>=0, y>=0, z>=1, x+y+z=2n+2) and/or CₘH_{q}ClᵣFₛ (m>=1, q>=0, r>=0, s>=1, q+r+s=2m+2).

As the carrier gas, at least one of H₂, Ar, HCl, and F₂ is applicable.

As the materials for dopant, N₂ or TMA is applicable.

### Fourth CVD Apparatus

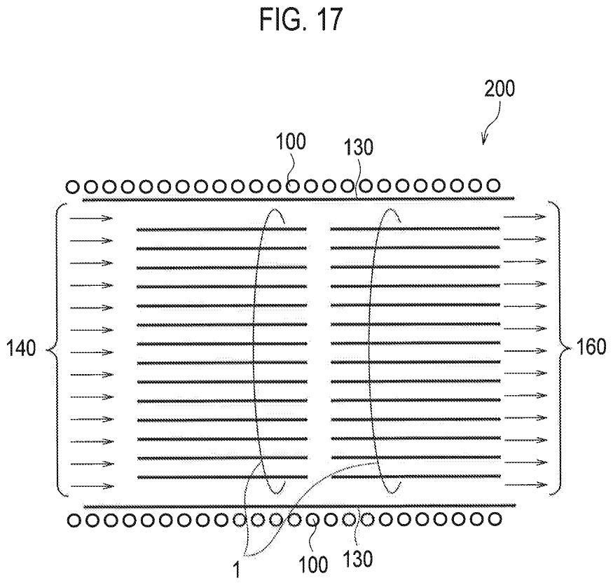

As shown in FIG. 17, in the manufacturing apparatus 200 of the SiC epitaxial wafer according to the embodiment, a schematic configuration example of a fourth CVD apparatus applicable to the SiC epitaxial growth includes a gas injection port 140, a gas exhaust port 160, a heating unit 100, and a horizontal-type reactor 130.

As a heating method of the heating unit 100, resistance heating, induction heating using a coil, lamp heating, etc. are adoptable. In the case of the induction heating method, a structural member made from carbon (not shown in FIG. 14) disposed near the wafer, the structural member made from carbon produces heat, and then the wafer in contact with the structural member is heated or the wafer is heated with radiation from the structural member made from carbon.

In the horizontal-type reactor 130, a plurality pieces of the SiC epitaxial wafers 1 can be disposed in a face up manner or face down manner.

While the material gas is supplied from the gas injection port 140 of the horizontal-type reactor 130, passes through the plurality pieces of the SiC epitaxial wafers 1, and then is exhausted from the gas exhaust port 160, the materials which flows on the surface of the plurality pieces of the SiC epitaxial wafers 1 react, thereby forming the SiC epitaxial growth layer.

The material gas to be supplied generally can be expressed with the following equation: namely, SiₙHₓCl_{y}F_{z} (n>=1, x>=0, y>=0, z>=1, x+y+z=2n+2) and/or CₘH_{q}ClᵣFₛ (m>=1, q>=0, r>=0, s>=1, q+r+s=2m+2).

As the carrier gas, at least one of H₂, Ar, HCl, and F₂ is applicable.

As the materials for dopant, N₂ or TMA is applicable.

The above-mentioned SiC epitaxial wafer is applicable to fabricating of various kinds of SiC semiconductor elements, for example. Hereinafter, there will be shown examples of an SiC Schottky Barrier Diode (SiC—SBD), an SiC Trench-gate type Metal Oxide Semiconductor Field Effect Transistor (Sic-TMOSFET), and an SiC planar-gate type MOSFET, as those examples. (SiC—SBD)

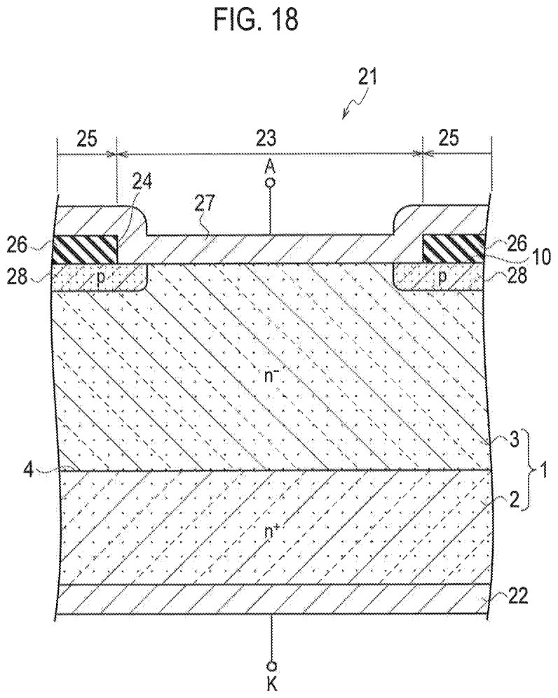

FIG. 18 shows a schematic cross-sectional structure of SiC—SBD 21 fabricated using the SiC epitaxial wafer according to the embodiment.

As shown in FIG. 18, the SiC—SBD 21 fabricated using the SiC epitaxial wafer according to the embodiment includes an SiC epitaxial wafer 1. The SiC epitaxial wafer 1 includes: an n⁺ type SiC substrate 2 (of which an impurity concentration is approximately 1×10¹⁸ cm⁻³ to approximately 1×10²¹ cm⁻³, for example); and an n⁻ type SiC epitaxial growth layer 3 (of which an impurity concentration is approximately 5×10¹⁴ cm⁻³ to approximately 5×10¹⁶ cm−³, for example). As an n-type doping impurities, nitrogen (N), phosphorus (P), arsenic (As), etc. are applicable, for example.

A back side surface ((000-1) C surface) of the SiC substrate 2 includes a cathode electrode 22 so as to cover the whole region of the back side surface, and the cathode electrode 22 is connected to a cathode terminal K.

A surface 10 ((0001) Si surface) of the SiC epitaxial growth layer 3 includes a contact hole 24 to which a part of the SiC epitaxial growth layer 3 is exposed as an active region 23, and a field insulating film 26 is formed at a field region 25 which surrounding the active region 23.

Although the field insulating film 26 includes silicon oxide (SiO₂), the field insulating film 26 may include other insulating materials, e.g. silicon nitride (SiN). An anode electrode 27 is formed on the field insulating film 26, and the anode electrode 27 is connected to an anode terminal A.

Near the surface 10 (surface portion) of the SiC epitaxial growth layer 3, a p-type Junction Termination Extension (JTE) structure 28 is formed so as to be contacted with the anode electrode 27. The JTE structure 28 is formed along an outline of the contact hole 24 so as to extend from the outside to inside of the contact hole 24 of the field insulating film 26.

According to the SiC—SBD 21 fabricated using the SiC epitaxial wafer according to the embodiment, a leakage current can be reduced.

### SiC-TMOSFET

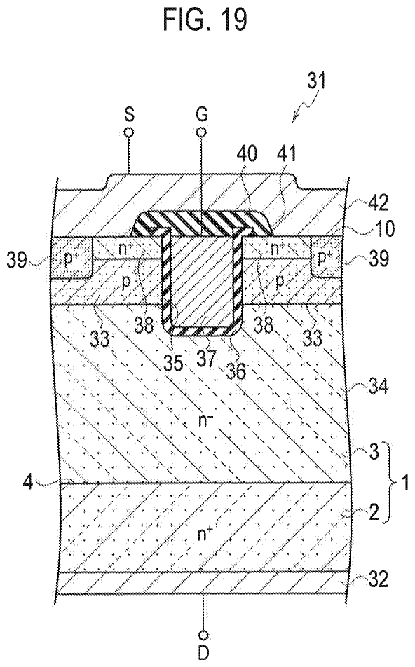

FIG. 19 shows a schematic cross-sectional structure of the SiC-TMOSFET 31 fabricated using the SiC epitaxial wafer according to the embodiment.

As shown in FIG. 19, the SiC-TMOSFET 31 fabricated using the SiC epitaxial wafer according to the embodiment includes an SiC epitaxial wafer 1. The SiC epitaxial wafer 1 includes: an n⁺ type SiC substrate 2 (of which an impurity concentration is approximately 1×10¹⁸ cm⁻³ to approximately 1×10²¹ cm⁻³, for example); and an n⁻ type SiC epitaxial growth layer 3 (of which an impurity concentration is approximately 5×10¹⁴ cm⁻³ to approximately 5×10¹⁶ cm⁻³, for example). As an n-type doping impurities, nitrogen (N), phosphorus (P), arsenic (As), etc. are applicable, for example.

A back side surface ((000-1) C surface) of the SiC substrate 2 includes a drain electrode 32 so as to cover the whole region of the back side surface, and the drain electrode 32 is connected to a drain terminal D.

Near the surface 10 ((0001) Si surface) (surface portion) of the SiC epitaxial growth layer 3, a p-type body region 33 (of which an impurity concentration is approximately 1×10¹⁶ cm⁻³ to approximately 1×10¹⁹ cm⁻³, for example) is formed. In the SiC epitaxial growth layer 3, a portion at a side of the SiC substrate 2 with respect to the body region 33 is an n⁻ type drain region 34 where a state after the epitaxial growth is still kept.

A gate trench 35 is formed in the SiC epitaxial growth layer 3. The gate trench 35 passes through the body region 33 from the surface 10 of the SiC epitaxial growth layer 3, and a deepest portion of the gate trench 35 extends to the drain region 34.

A gate insulating film 36 is formed on an inner surface of the gate trench 35 and the surface 10 of the SiC epitaxial growth layer 3 so as to cover the whole of the inner surface of the gate trench 35. Moreover, a gate electrode 37 is embedded in the gate trench 35 by filling up the inside of the gate insulating film 36 with polysilicon, for example. A gate terminal G is connected to the gate electrode 37.

An n⁺ type source region 38 forming a part of a side surface of the gate trench 35 is formed on a surface portion of the body region 33.

Moreover, a p⁺ type body contact region 39 (of which an impurity concentration is approximately 1×10¹⁸ cm⁻³ to approximately 1×10²¹ cm⁻³, for example) which passes through the source region 38 from the surface 10 and is connected to the body region 33 is formed on the SiC epitaxial growth layer 3.

An interlayer insulating film 40 including SiO₂ is formed on the SiC epitaxial growth layer 3. A source electrode 42 is connected to the source region 38 and the body contact region 39 through a contact hole 41 formed in the interlayer insulating film 40. A source terminal S is connected to the source electrode 42.

A predetermined voltage (voltage equal to or greater than a gate threshold voltage) is applied to the gate electrode 37 in a state where a predetermined potential difference is generated between the source electrode 42 and the drain electrode 32 (between the source and the drain). Thereby, a channel can be formed by an electric field from the gate electrode 37 near the interface between the gate insulating film 36 and the body region 33. Thus, an electric current can be flowed between the source electrode 42 and the drain electrode 32, and thereby the SiC-TMOSFET 31 can be turned ON state.

The SiC-TMOSFET 31 fabricated using the SiC epitaxial wafer according to the embodiment can improve a carrier mobility and can offer enhanced speed.

### SiC Planar-Gate Type MOSFET

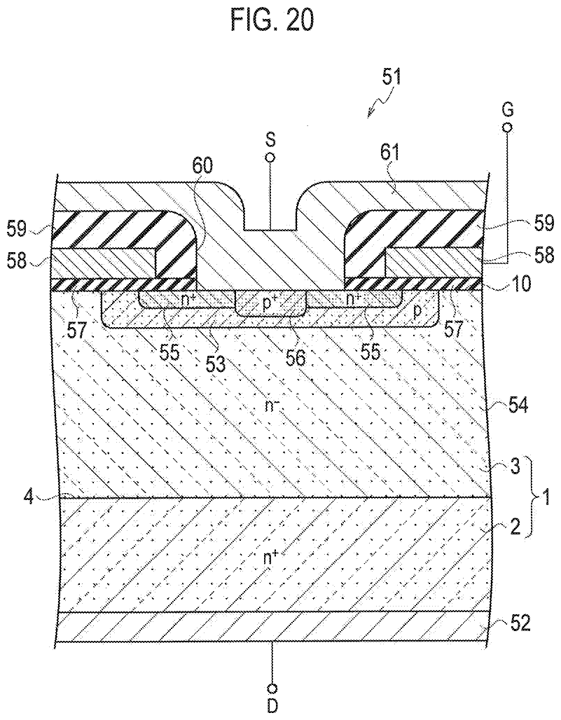

FIG. 20 shows a schematic cross-sectional structure of the planar-gate type SiC-MOSFET fabricated using the SiC epitaxial wafer according to the embodiment.

As shown in FIG. 20, the planar-gate type SiC-MOSFET 51 fabricated using the SiC epitaxial wafer according to the embodiment includes an SiC epitaxial wafer 1. The SiC epitaxial wafer 1 includes: an n⁺ type SiC substrate 2 (of which an impurity concentration is approximately 1×10¹⁸ cm⁻³ to approximately 1×10²¹ cm⁻³, for example); and an n⁻ type SiC epitaxial growth layer 3 (of which an impurity concentration is approximately 5×10¹⁴ cm⁻³ to approximately 5×10¹⁶ cm⁻³, for example).

A back side surface ((000-1) C surface) of the SiC substrate 2 includes a drain electrode 52 so as to cover the whole region of the back side surface, and the drain electrode 52 is connected to a drain terminal D.

Near the surface 10 ((0001) Si surface) (surface portion) of the SiC epitaxial growth layer 3, a p-type body region 53 (of which an impurity concentration is approximately 1×10¹⁶ cm to approximately 1×10¹⁹ cm⁻³, for example) is formed in a well shape. In the SiC epitaxial growth layer 3, a portion at a side of the SiC substrate 2 with respect to the body region 53 is an n⁻ type drain region 54 where a state after the epitaxial growth is still kept.

An n⁺ type source region 55 is formed on a surface portion of the body region 53 with a certain space from a periphery of the body region 53.

A p⁺ type body contact region 56 (of which an impurity concentration is approximately 1×10¹⁸ cm⁻³ to approximately 1×10²¹ cm⁻³, for example) is formed inside of the source region 55. The body contact region 56 passes through the source region 55 in a depth direction, and is connected to the body region 53.

A gate insulating film 57 is formed on the surface 10 of the SiC epitaxial growth layer 3. The gate insulating film 57 covers the portion surrounding the source region 55 in the body region 53 (peripheral portion of the body region 53), and an outer peripheral portion of the source region 55.

A gate electrode 58 including polysilicon, for example, is formed on the gate insulating film 57. The gate electrode 58 is opposed to the peripheral portion of the body region 53 by sandwiching the gate insulating film 57. A gate terminal G is connected to the gate electrode 58.

An interlayer insulating film 59 including SiO₂ is formed on the SiC epitaxial growth layer 3. A source electrode 61 is connected to the source region 55 and the body contact region 56 through a contact hole 60 formed in the interlayer insulating film 59. A source terminal S is connected to the source electrode 61.

A predetermined voltage (voltage equal to or greater than a gate threshold voltage) is applied to the gate electrode 58 in a state where a predetermined potential difference is generated between the source electrode 61 and the drain electrode 52 (between the source and the drain). Thereby, a channel can be formed by an electric field from the gate electrode 58 near the interface between the gate insulating film 57 and the body region 53. Thus, an electric current can be flowed between the source electrode 61 and the drain electrode 52, and thereby the planar-gate type MOSFET 51 can be turned ON state.

The planar-gate type MOSFET 51 also can improve a carrier mobility and can offer enhanced speed, similarly to the SiC-TMOSFET 31 shown in FIG. 19.

Although the embodiment has been explained above, the embodiment can also be implemented with other configurations.

For example, the principal surface 4 (substrate surface) of the SiC substrate 2 may be inclined in the OFF direction of [−1100] axis with respect to the (0001) surface by the off angle θ equal to or less than 4 degrees. Although illustration is omitted, MOS capacitors can also be fabricated using the SiC epitaxial wafer according to the embodiment. According to the MOS capacitors, a yield and reliability can be improved. Moreover, with regard to the reliability, initial failures can be reduced.

Although illustration is omitted, bipolar junction transistors can also be fabricated using the SiC epitaxial wafer according to the embodiment. In addition, the SiC epitaxial wafer according to the embodiment can also be used for fabricating of SiC-pn diodes, SiC Insulated Gate Bipolar Transistor (IGBT), SiC complementary MOSFET, etc.

According to the SiC epitaxial wafer according to the embodiment, defect regions on the surface or interface of the SiC epitaxial growth layer can be reduced. Therefore, a leakage current, ununiformity of the oxide film thickness, interface state density, surface recombination, etc. are reduced, and thereby field effect mobility can be improved. Accordingly, there can be provided the high quality SiC semiconductor device having high reliability.

According to the embodiment, there can be provided the high quality SiC epitaxial wafer having few surface defects and having excellent film thickness uniformity and carrier density uniformity, the manufacturing apparatus of the SiC epitaxial wafer, the fabrication method of the SiC epitaxial wafer, and the semiconductor device.

### Other Embodiments

As mentioned above, although the SiC epitaxial wafer, the manufacturing apparatus of the SiC epitaxial wafer, the fabrication method of the SiC epitaxial wafer, and the semiconductor device have been described, as a disclosure including associated description and drawings to be construed as illustrative, not restrictive. This disclosure makes clear a variety of alternative embodiment, working examples, and operational techniques for those skilled in the art.

Such being the case, the embodiments cover a variety of embodiments, whether described or not.

### INDUSTRIAL APPLICABILITY

The semiconductor device to which the SiC epitaxial wafer according to the embodiment is applied can be applied to wide applicable fields, e.g., power modules for inverter circuits for driving electric motors utilized as sources of power of electric vehicles (including hybrid cars), trains, industrial robots; and power modules for inverter circuits for transforming electric power generated by electric generators (e.g., solar cells, wind power generators, and the like (in particular private electric generators)) into electric power for commercial power sources, etc.

1-5. (canceled)

6. A fabrication method of a silicon carbide epitaxial wafer comprising:
preparing an SiC ingot, cutting the prepared SiC ingot with an off angle, and polishing the cut SiC ingot to form an SiC bare wafer;
removing a cut surface of the SiC bare wafer to form an SiC substrate; and
crystal-growing an SiC epitaxial growth layer on the SiC substrate, wherein
a material gas to be supplied at the time of the epitaxial growth comprises an Si compound gas used as a supply source of Si, and Carbon (C) compound gas used as a supply source of C, wherein
any one or both of the Si compound gas and the C compound gas comprises a compound gas containing Fluorine (F), wherein
a surface-roughness defect density including particles on a surface of the SiC epitaxial growth layer is controlled to be less than 1.0 cm⁻².

7. The fabrication method of the silicon carbide epitaxial wafer according to claim 6, wherein
the Si compound comprises one selected from the group consisting of SiF₄, SiH₃F, SiH₂F₂, and SiHF₃.

8. The fabrication method of the silicon carbide epitaxial wafer according to claim 6, wherein
the Si compound is expressed with SiₙHₓCl_{y}F_{z} (n>=1, x>=0, y>=0, z>=1, x+y+z=2n+2).

9. The fabrication method of the silicon carbide epitaxial wafer according to claim 6, wherein
the C compound comprises one selected from the group consisting of CF₄, C₂F₆, C₃F₈, C₄F₆, C₄F₈, C₅F₈, CHF₃, CH₂F₂, CH₃F, and C₂HF₅.

10. The fabrication method of the silicon carbide epitaxial wafer according to claim 6, wherein
the C compound is expressed with CₘH_{q}ClᵣFₛ (m>=1, q>=0, r>=0, s>=1, q+r+s=2m+2).

11. The fabrication method of the silicon carbide epitaxial wafer according to claim 6, wherein
the SiC epitaxial growth layer comprises one selected from the group consisting of 4H—SiC, 6H—SiC, 2H—SiC and 3C—SiC.

12. The fabrication method of the silicon carbide epitaxial wafer according to claim 6, wherein
in a temperature profile of the crystal growth of the SiC epitaxial growth layer, a predetermined temperature of hydrogen etching immediately before depositing the SiC epitaxial growth layer is not the same as a predetermined temperature of depositing the SiC epitaxial growth layer.

13. The fabrication method of the silicon carbide epitaxial wafer according to claim 6, wherein
the temperature profile of the crystal growth of the SiC epitaxial growth layer is controlled to be a hydrogen etching temperature in accordance with a hydrogen flow rate.

14-23. (canceled)

24. The fabrication method of the silicon carbide epitaxial wafer according to claim 6, wherein
a surface of the SiC bare wafer is a (0001) surface.

25. The fabrication method of the silicon carbide epitaxial wafer according to claim 6, wherein
the Si compound gas or each the Si compound gas and the C compound gas comprises a compound gas containing Fluorine (F).

26. The fabrication method of the silicon carbide epitaxial wafer according to claim 6, wherein
a crystal growth temperature is controlled so that the surface-roughness defect density is less than 0.07 cm⁻².

27. The fabrication method of the silicon carbide epitaxial wafer according to claim 6, wherein
in a temperature profile of the crystal growth of the SiC epitaxial growth layer, a predetermined temperature of hydrogen etching immediately before depositing the SiC epitaxial growth layer is the same as a predetermined temperature of depositing the SiC epitaxial growth layer.

28. The fabrication method of the silicon carbide epitaxial wafer according to claim 6, wherein
a thickness of the substrate is approximately 200 μm to approximately 500 μm, and a thickness of the SiC epitaxial growth layer is approximately 4 μm to approximately 100 μm.

29. The fabrication method of the silicon carbide epitaxial wafer according to claim 6, wherein
an off angle of the SiC epitaxial growth layer is equal to or less than 4 degrees, and a diameter of the substrate is approximately 150 mm.
